(19) United States
(12) Patent Application Publication
(10) Pub. No.: US 2008/0144295 A1
(43) Pub. Date: Jun. 19, 2008

(54) FLEXIBLE PRINTED CIRCUIT BOARD

(75) Inventors: MING WANG, Shenzhen (CN); I-HSIEN CHIANG, Tayuan (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN ADVANCED TECHNOLOGY INC., Tayuan (TW)

(21) Appl. No.: 11/733,173

(22) Filed: Apr. 9, 2007

(30) Foreign Application Priority Data
Dec. 15, 2006 (CN) 200610157551.4

(51) Int. Cl. H05K 1/00

(52) U.S. Cl. 361/750

(57) ABSTRACT

An exemplary flexible printed circuit board includes a flexible base film, a number of signal traces formed on the flexible base film, and at least a grounding metal layer formed on the flexible base film. The grounding metal layer defines a number of openings therein thereby forming a mesh-like pattern. The flexible printed circuit board can disperse and reduce stress caused by bending, thereby preventing wires from becoming broken/cracked and enhancing flexibility.

### BACKGROUND

1. Technical Field

The present invention relates to flexible printed circuit boards and, more particularly to a flexible printed circuit board with excellent flexibility.

2. Description of Related Art

In recent years, flexible printed circuit boards (FPCBs) are widely used in portable electronic devices such as mobile phones for electrical connection. Mobile phones, especially folding mobile phones and slide mobile phones, demand flexible printed circuit boards that can be repeatedly bent and re-bent. Generally, it is expected that a flexible printed circuit board for use in mobile phones can be bent from about 80,000 to about 100,000 times before breaking.

Referring to FIG. 10, a typical flexible printed circuit board 10 is shown. The flexible printed circuit board 10 includes a flexible base film 111, a number of signal traces 121 formed on the flexible base film 111 and two grounding metal layers 141 formed on the flexible base film 111. The two grounding metal layers 141 are on two sides of the signal traces 121 so as to adequately shield them from electromagnetic interferences (EMI). Each grounding metal layer 141 is a large whole piece of copper foil. However, when the flexible printed circuit board 10 is bent, stresses produced in the grounding metal layers 141 cannot be dispersed in time and the grounding metal layers 141 are prone to experience breakage/cracking. Moreover, the stresses produced can be transferred from the grounding metal layers 141 to the signal traces 121, thereby causing the signal traces 121 to break/crack. Therefore, the flexible printed circuit board 10 generally can be bent only about 50,000 to 70,000 times before breaking/cracking. Thus it can be seen that the flexible printed circuit board 10 lacks the level of flexibility needed in portable electronic devices such as mobile phones.

What is needed, therefore, is a flexible printed circuit board with excellent flexibility.

### SUMMARY

One preferred embodiment provides a flexible printed circuit board. The flexible printed circuit board includes a flexible base film, a number of signal traces formed on the flexible base film, and at least a grounding metal layer formed on the flexible base film. The grounding metal layer defines a number of openings therein thereby forming a mesh-like pattern.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of a flexible printed circuit board according to a first embodiment;

FIG. 2 is a schematic, cross-sectional view of substrate of the flexible printed circuit board according to the first embodiment;

FIG. 3 is a schematic view of a first wiring pattern of the flexible printed circuit board according to the first embodiment;

FIG. 4 is a schematic view of a second wiring pattern of the flexible printed circuit board according to the first embodiment;

FIG. 5 is a schematic view of a third wiring pattern of the flexible printed circuit board according to the first embodiment;

FIG. 6 is a schematic, cross-sectional view of substrate of a flexible printed circuit board according to a second embodiment;

FIG. 7 is a schematic view of a first wiring pattern of the flexible printed circuit board according to the second embodiment;

FIG. 8 is a schematic view of a second wiring pattern of the flexible printed circuit board according to the second embodiment;

FIG. 9 is a schematic view of a third wiring pattern of the flexible printed circuit board according to the second embodiment; and

FIG. 10 is a schematic view of a typical flexible printed circuit board.

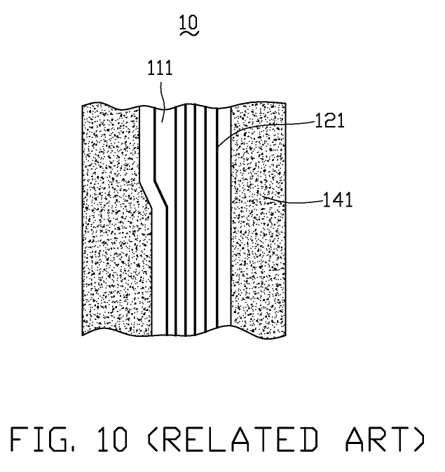

### DETAILED DESCRIPTION OF THE EMBODIMENTS

Embodiments will now be described in detail below and with reference to the drawings.

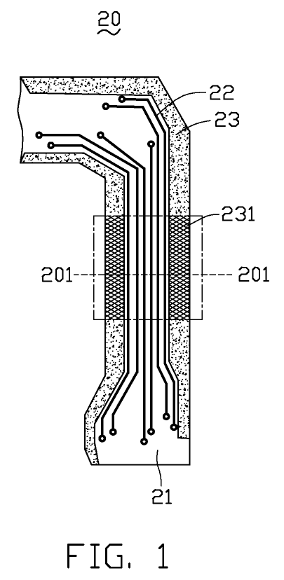

Referring to FIG. 1, a flexible printed circuit board 20 according to a first exemplary embodiment is shown. The flexible printed circuit board 20 includes a flexible base film 21, a number of signal traces 22 formed on the flexible base film 21, and two grounding metal layers 23 formed on the flexible base film 21. The flexible printed circuit board 20 can be bent along a bending axis 201 (i.e., a line along which the flexible printed circuit board bends/hinges). The two grounding metal layers 23 are on edge portions of the flexible base film 21. Thus, the two grounding metal layers 23 are on two sides of the signal traces 22 so as to adequately shield the signal traces 22 from electromagnetic interference (EMI). Each grounding metal layer 23 defines a number of openings 231 therein, thus each grounding metal layer 23 forms a mesh-like pattern. A ratio of area of the openings 231 in each grounding metal layer 23 to that of each grounding metal layer 23 is in the approximate range from 0.4 to 0.7. The flexible printed circuit board 20 can disperse and reduce stress caused by bending, thereby preventing the signal traces 22 and the grounding metal layers 23 from breaking/cracking and enhancing flexibility.

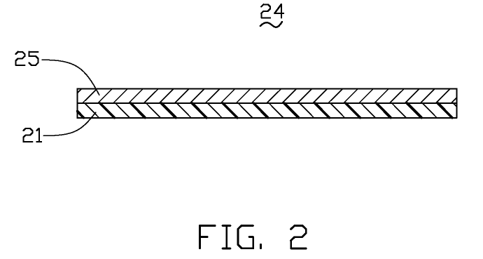

Referring to FIG. 2, the flexible printed circuit board 20 is a single-layer flexible printed circuit board, which is made of a single-layer conductive-metal-clad substrate 24 including a flexible base film 21 and a conductive metal layer 25. The flexible base film 21 can be a polyimide film or a polyester film. The conductive metal layer 25 can be a copper layer. The conductive metal layer 25 is configured (i.e., structured and arranged) to form the signal traces 22 and the two grounding metal layers 23. No conductive metal of the conductive metal layer 25 exists where the openings 231 are. The openings 231 can be various configurations, including parallelogram-shaped and circular according to different flexible printed circuit boards, thus allowing various mesh-like patterns to be formed.

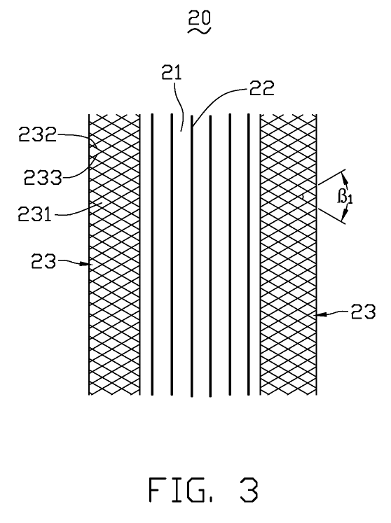

Referring to FIG. 3, a first wiring pattern of the flexible printed circuit board 20 is shown. The openings 231 each have an essentially identical parallelogram-shaped configuration. In the embodiment, the openings 231 are rhombic openings having similar sizes. The openings 231 can be distributed uniformly and regularly. For example, the openings 231 can be arranged in a staggered fashion, thus the grounding metal of the grounding metal layer 23 can form a number of first metal lines 232 and a number of second metal lines 233 intersecting the first metal lines 232. The first metal lines 232 are parallel to each other; similarly, the second metal lines 233 also are parallel to each other. Therefore, the grounding metal layer 23 can form a mesh-like pattern.

In the embodiment, the rhombic openings 231 each have an essentially identical acute angle β₁ in an approximate range from 30 to 80 degrees. Because the grounding metal of the grounding metal layer 23 forms the first metal lines 232 and the second metal lines 233 intersecting the first metal lines 232. Therefore, an angle of the first metal lines 232 to the second metal lines 233 is in an approximate range from 30 to 80 degrees. In the embodiment, the rhombic openings 231 each have an essentially identical acute angle β₁ of 60 degrees.

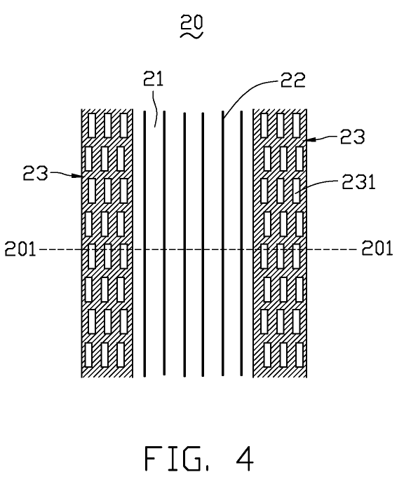

Referring to FIG. 4, a second wiring pattern of the flexible printed circuit board 20 is shown. Also, the openings 231 each have an essentially identical parallelogram-shaped configuration. In the embodiment, the openings 231 are rectangular openings, and the grounding metal layer 23 forms a mesh-like pattern. The openings 231 can have similar sizes. The openings 231 can be distributed uniformly and regularly. For example, the openings 231 can be arranged in an array. In the embodiment, lateral sides of the openings 231 are perpendicular to the bending axis 201 of the flexible printed circuit board 20. Alternatively, lateral sides of the openings 231 can be parallel to the bending axis 201 of the flexible printed circuit board 20. A width of each of the openings 231 is in an approximate range from 0.1 to 0.5 millimeters.

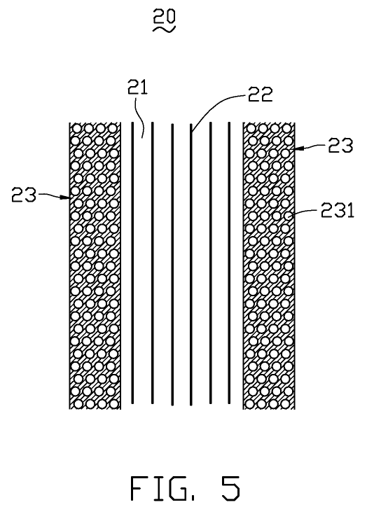

Referring to FIG. 5, a third wiring pattern of the flexible printed circuit board 20 is shown. In the embodiment, the openings 231 each have an essentially identical circular configuration, and the grounding metal layer 23 forms a mesh-like pattern. A diameter of each of the openings 231 is in an approximate range from 0.5 to 2.0 millimeters. The openings 231 can have similar sizes and be distributed uniformly. For example, the openings 231 can be arranged in an array.

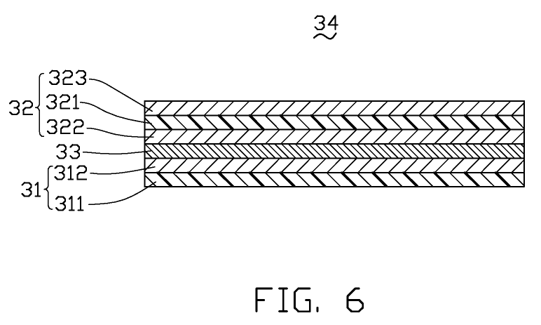

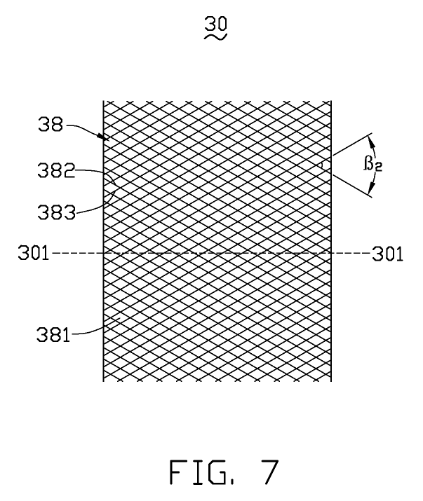

Referring to FIG. 6 and FIG. 7, a flexible printed circuit board 30 according to a second exemplary embodiment is shown. The flexible printed circuit board 30 is a multi-layer flexible printed circuit board, which is made of a multi-layer conductive-metal-clad substrate 34. The multi-layer conductive-metal-clad substrate 34 includes a first conductive-metal-clad substrate 31, a second conductive-metal-clad substrate 32 and an adhesive layer 33.

The first conductive-metal-clad substrate 31 is a single-sided conductive-metal-clad substrate including a first flexible base film 311 and a first conductive metal layer 312. The second conductive-metal-clad substrate 32 is a double-sided conductive-metal-clad substrate including a second flexible base film 321, a second conductive metal layer 322 and a third conductive metal layer 323. The second conductive metal layer 322 and the third conductive metal layer 323 are disposed on opposite sides of the second flexible base film 321. The adhesive layer 33 is disposed between the first conductive metal layer 312 and the second conductive metal layer 322. In this way, the first conductive-metal-clad substrate 31 and the second conductive-metal-clad substrate 32 form a multi-layer conductive-metal-clad substrate. Therefore, the multi-layer conductive-metal-clad substrate includes the first flexible base film 311, the first conductive metal layer 312, the adhesive layer 33, the second conductive metal layer 322, the second flexible base film 321 and the third conductive metal layer 323 placed one on top of the other in that order. The first conductive metal layer 321 and the second conductive metal 322 are inner conductive metal layers of the flexible printed circuit board 30 and configured to form signal traces. The third conductive metal layer 323 is an outermost conductive metal layer of the flexible printed circuit board 30 and configure for forming grounding metal layer. The first flexible base film 311 and the second flexible film 321 can be polyimide film or polyester film. The first conductive metal layer 321, the second conductive metal 322 and the third conductive metal layer 323 can be copper layers.

Additionally, the first conductive-metal-clad substrate 31 and the second conductive-metal-clad substrate 32 can be multi-layer conductive-metal-clad substrates, thus giving more inner conductive metal layers configured to form signal traces.

Referring to FIG. 6 and FIG. 7, the flexible printed circuit board 30 can be bent along a bending axis 301. The flexible printed circuit board 30 includes a number of signal traces (not shown) on the first flexible base film 311 and the second flexible base film 321 and a grounding metal layer 38 formed on the second flexible base film 321. The signal traces are formed with the inner conductive metal layers such as the first conductive metal layer 312 and the second conductive metal layer 322. The grounding metal layer 38 is formed with the third conductive metal layer 323. Thus, the grounding metal layer 38 and the signal traces are formed on opposite sides of the second flexible base film 312. The grounding metal layers 38 defines a number of openings 381 therein, thus the grounding metal layer 38 forms a mesh-like pattern. The openings 381 each have an essentially identical parallelogram-shaped configuration. A ratio of area of the openings 381 in the grounding metal layer 38 to that of the grounding metal layer 38 is in the approximate range from 0.4 to 0.7. The flexible printed circuit board 30 can disperse and reduce stress caused by bending, thereby preventing the signal traces and the grounding metal layer 38 from breaking and enhancing flexibility.

In the embodiment, the openings 381 are rhomboid-shaped openings having similar sizes. The openings 381 can be distributed uniformly and regularly. For example, the openings 381 are arranged in a staggered fashion, thus the grounding metal of the grounding metal layer 38 can form a number of first metal lines 382 and a number of second metal lines 383 intersecting the first metal lines 382. The first metal lines 382 are parallel to each other; similarly, the second metal lines 383 also are parallel to each other. Therefore, the grounding metal layer 38 forms a mesh-like pattern. The openings 231 each have an essentially identical acute angle β₂ in an approximate range from 30 to 80 degrees. Because the grounding metal of the grounding metal layer 38 forms the first metal lines 382 and the second metal lines 383 intersecting the first metal lines 382. Therefore, an angle of the first metal lines 382 to the second metal lines 383 is in an approximate range from 30 to 80 degrees. In the embodiment, the openings 231 each have an essentially identical acute angle β₂ of 60 degrees.

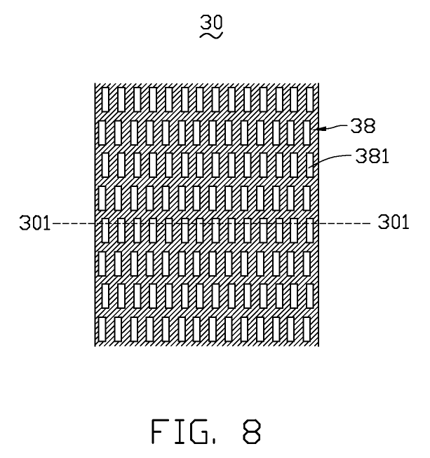

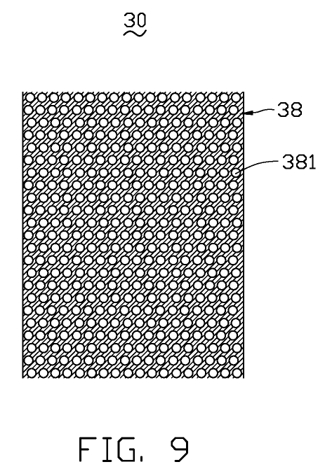

The openings 381 can be various configurations according to different flexible printed circuit boards, thereby forming various mesh-like patterns. Referring to FIG. 8, the openings 381 each have an essentially identical rectangular configuration, and the grounding metal layer 38 forms a mesh-like pattern. The openings 381 can have similar sizes. The openings 231 can be distributed uniformly and regularly. For example, the openings 381 can be arranged in an array. In the embodiment, lateral sides of the openings 381 are perpendicular to the bending axis 301 of the flexible printed circuit board 30. Alternatively, lateral sides of the openings 381 can be parallel to the bending axis 301 of the flexible printed circuit board 30. A width of each of the openings 381 is in an approximate range from 0.1 to 0.5 millimeters. Referring to FIG. 9, the openings 381 each have an essentially identical circular configuration, and the grounding metal layer 38 forms a mesh-like pattern. A diameter of each of the openings 381 is in an approximate range from 0.5 to 2.0 millimeters. The openings 381 can have similar sizes and be distributed uniformly. For example, the openings 381 can be arranged in an array.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A flexible printed circuit board comprising:
a flexible base film;
a plurality of signal traces formed on the flexible base film; and
at least a grounding metal layer formed on the flexible base film, the grounding metal layer defining a plurality of openings therein thereby forming a mesh-like pattern.

2. The flexible printed circuit board as claimed in claim 1, wherein the openings each have an essentially identical parallelogram-shaped configuration.

3. The flexible printed circuit board as claimed in claim 2, wherein the openings each have an essentially identical rhomboid-shaped configuration.

4. The flexible printed circuit board as claimed in claim 3, wherein the openings each have an essentially identical acute angle in an approximate range from 30 to 60 degrees.

5. The flexible printed circuit board as claimed in claim 2, wherein the openings each have an essentially identical rectangular configuration.

6. The flexible printed circuit board as claimed in claim 5, wherein a width of each of the openings is in an approximate range from 0.1 to 0.5 millimeters.

7. The flexible printed circuit board as claimed in claim 1, wherein the openings each have an essentially identical circular configuration.

8. The flexible printed circuit board as claimed in claim 7, wherein a diameter of each of the openings is in an approximate range from 0.5 to 2.0 millimeters.

9. The flexible printed circuit board as claimed in claim 1, wherein the openings have similar sizes.

10. The flexible printed circuit board as claimed in claim 1, wherein the openings are arranged in a staggered fashion.

11. The flexible printed circuit board as claimed in claim 1, wherein the openings are arranged in an array.

12. The flexible printed circuit board as claimed in claim 1, wherein a ratio of area of the openings to that of the grounding metal layer is in the approximate range from 0.4 to 0.7.

13. The flexible printed circuit board as claimed in claim 1, wherein the grounding metal layer is formed on edge portions of the flexible base film.

14. The flexible printed circuit board as claimed in claim 1, wherein the grounding metal layer and the signal traces are formed on opposite sides of the flexible base film.
